(19) United States
(12) Patent Application Publication
(10) Pub. No.: US 2023/0305043 A1
(43) Pub. Date: Sep. 28, 2023

(54) POWER CONSUMPTION MONITORING APPARATUS

(71) Applicant: Mitsubishi Electric Corporation, Tokyo (JP)

(72) Inventors: Toshihiro MEGA, Tokyo (JP); Tomohiro NARUI, Tokyo (JP); Shuichi MURAYAMA, Tokyo (JP); Fuyuki SATO, Tokyo (JP); Genta YOSHIMURA, Tokyo (JP)

(73) Assignee: Mitsubishi Electric Corporation, Tokyo (JP)

(21) Appl. No.: 18/200,106

(22) Filed: May 22, 2023

Related U.S. Application Data
(63) Continuation of application No. PCT/JP2020/043804, filed on Nov. 25, 2020.

(51) Int. Cl. G01R 21/00; G06Q 50/06

(52) U.S. Cl. CPC G01R 21/00; G06Q 50/06

(57) ABSTRACT

An energy conservation assistance apparatus includes an event occurrence time extraction unit, a degree of change calculation unit, and a display control unit. The event occurrence time extraction unit refers to facility operation history information included in a reference period and a designated period to extract occurrence times at which a predetermined event has occurred in each of the reference period and the period of interest. The degree of change calculation unit calculates a degree of change in an operation pattern of a facility obtained from a distribution of the occurrence times at which the predetermined event has occurred in the period of interest, relative to an operation pattern of the facility obtained from a distribution of the occurrence times at which the predetermined event has occurred in the reference period. The display control unit presents information regarding a degree of change to a user.

### CROSS REFERENCE TO RELATED APPLICATION

This application is a continuation application of PCT/JP2020/043804 filed on Nov. 25, 2020, which is incorporated herein by reference in its entirety including the specification, claims, drawings, and abstract.

### TECHNICAL FIELD

The present disclosure relates to a power consumption monitoring apparatus and, in particular, to detection of a change in power consumption.

### BACKGROUND

In some office buildings, an energy conservation control plan is created based on power consumption prediction for the coming one year by taking into consideration the past actual data of the building, such as power consumption or facility operation history in the past one year. However, if a facility that is a component of the office building is changed in some way due to, for example, renewal of the facility, a change in use pattern, or any other change to the facility, there may arise a possibility that the power consumption or operation pattern of the facility will change. Therefore, in some cases, an energy conservation control plan cannot be created accurately unless the above-described changes are incorporated into power consumption prediction.

In consideration of the above, there has heretofore been proposed a technique comprising measuring a current waveform and a voltage waveform of power consumption for each facility and, when a change that is inconsistent with a power consumption pattern that represents the characteristics of fluctuation amounts of power consumption is observed in estimated power obtained from the measurement values, correcting the estimated power (see, for example, Patent Document 1).

### CITATION LIST

### Patent Literature

Patent Document 1: JP 2015-102526 A
Patent Document 2: JP 2017-067427 A
Patent Document 3: JP 2016-058029 A
Patent Document 4: JP 2019-049404 A
Patent Document 5: JP 2017-097578 A
Patent Document 6: JP 2007-226415 A
Patent Document 7: JP 2014-017542 A
Patent Document 8: WO 2017/090172

### SUMMARY

As described above, a change in operation pattern of a facility may also cause a change in power consumption of the facility. However, in order to identify a change in power consumption for each of facilities, conventional techniques assume as a precondition that power consumption of each of the facility can be measured, which involves facility costs for these measurements.

The present disclosure is directed toward enabling indication of a possibility of change in power consumption for each of facilities without measuring power consumption of each of the facilities.

According to an aspect of the present disclosure, there is provided a power consumption monitoring apparatus comprising a processor, the processor being configured to refer to facility operation history information to extract occurrence times at which a predetermined event has occurred in each of a reference period and a period of interest, the reference period serving as a reference for analyzing power consumption of a facility, and the period of interest serving as a subject of analysis, to calculate a degree of change in an operation pattern of the facility obtained from a distribution of the occurrence times at which the predetermined event has occurred in the period of interest, relative to an operation pattern of the facility obtained from a distribution of the occurrence times at which the predetermined event has occurred in the reference period; and to output the calculated degree of change.

The predetermined event may be a power-on or power-off event of the facility.

The facility may be an air conditioning facility, and the predetermined event may be an event that a setting of the air conditioning facility has been changed to match a predetermined occurrence condition.

The processor may calculate a KL divergence or a JS divergence as a degree of change.

The processor may calculate a KS test statistic or an Anderson-Darling test statistic as a degree of change.

Multiple events may be set as the predetermined event, and the processor may calculate a degree of change for each event and may weight the degrees of change that are calculated for the respective events, to calculate a single degree of change.

The present disclosure enables indication of a possibility of change in power consumption for each of facilities without measuring power consumption of each of the facilities.

### BRIEF DESCRIPTION OF DRAWINGS

Embodiments of the present disclosure will be described based on the following figures, wherein:

FIG. 1 is a block schematic diagram illustrating an energy conservation assistance apparatus according to an embodiment of the present disclosure:

FIG. 2 is a hardware schematic diagram of the energy conservation assistance apparatus according to the embodiment;

FIG. 3 is a flowchart of an energy conservation assistance process according to the embodiment;

FIG. 4 illustrates an event occurrence count for each of a reference period and a period of interest in the form of a probability density distribution according to the embodiment:

FIG. 5 illustrates an event occurrence count for each of a reference period and a period of interest in the form of a cumulative probability distribution according to the embodiment;

FIG. 6 illustrates an example of display of information regarding a degree of change for presentation to a user according to the embodiment;

FIG. 7 illustrates another example of display of information regarding a degree of change for presentation to a user according to the embodiment:

FIG. 8 illustrates another example of display of information regarding a degree of change for presentation to a user according to the embodiment;

FIG. 9 illustrates another example of display of information regarding a degree of change for presentation to a user according to the embodiment; and

FIG. 10 illustrates another example of display of information regarding a degree of change for presentation to a user according to the embodiment.

### DESCRIPTION OF EMBODIMENTS

An embodiment of the present disclosure will be described below with reference to the accompanying drawings.

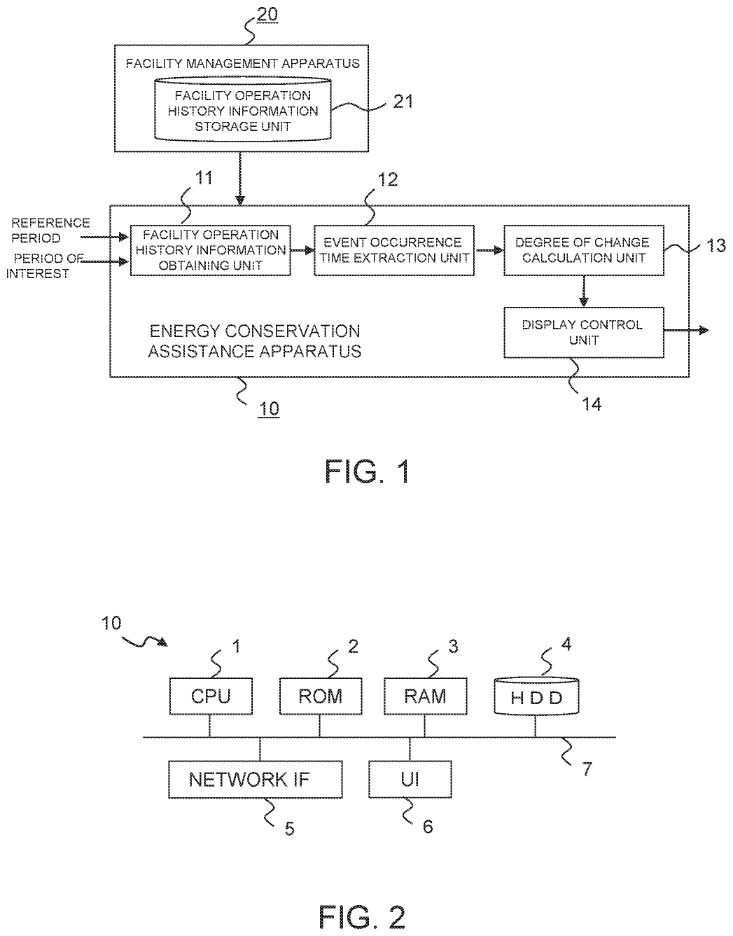

FIG. 1 is a block schematic diagram illustrating an energy conservation assistance apparatus 10 according to an embodiment of the present disclosure. The energy conservation assistance apparatus 10 according to the embodiment serves as an embodiment of the power consumption monitoring apparatus of the present disclosure and provides information that is useful for creating an energy conservation control plan to, for example, a planner using the functions of the power consumption monitoring apparatus. The energy conservation assistance apparatus 10 according to the embodiment can be implemented using a conventional general-purpose hardware structure such as a personal computer (PC).

FIG. 2 is a hardware schematic diagram of a computer that forms the energy conservation assistance apparatus 10 according to an embodiment of the present disclosure. As illustrated in FIG. 2, the energy conservation assistance apparatus 10 includes a CPU 1, a ROM 2, a RAM 3, a hard disk drive (HDD) 4 serving as storage means, a network interface (IF) 5 provided as communication means, and a user interface 6 including input means such as a mouse and a keyboard and display means such as a display, all of which are connected via an internal bus 7.

FIG. 1 illustrates the energy conservation assistance apparatus 10 and a facility management apparatus 20. The energy conservation assistance apparatus 10 and the facility management apparatus 20 are communicatively connected to each other over a network, which is not illustrated.

The facility management apparatus 20 collects and manages, for example, data that are directly obtained from facilities such as air conditioning or lighting installed in a building or another premise, or measurement data that are obtained via, for example, a sensor installed for each facility. Data to be collected include, for example, data that indicate power on/off, the state of each facility, or a set value. By processing collected data as appropriate, facility operation history information that indicates the state of operation of a facility is generated, and is stored in a facility operation history information storage unit 21. The facility operation history information includes, for example, dates and times when data are collected, corresponding facility identification information, facility types, data types, state values, set values, measurement values, or other data values.

The energy conservation assistance apparatus 10 analyzes the facility operation history information, thereby generating planning assistance information to provide it to a user, such as a planner whose job is to make plans, as assistance information that is useful for creating an energy conservation control plan. The energy conservation assistance apparatus 10 includes a facility operation history information obtaining unit 11, an event occurrence time extraction unit 12, a degree of change calculation unit 13, and a display control unit 14. It should be noted that elements that are not included in the description of the embodiment of the present disclosure are not illustrated in the figures.

The facility operation history information obtaining unit 11 obtains, from the facility management apparatus 20, facility operation history information included in a reference period and a designated period that are designated by a user. The event occurrence time extraction unit 12 refers to the obtained facility operation history information and extracts occurrence times at which a predetermined event has occurred in each of the reference period and the period of interest. The degree of change calculation unit 13 calculates a degree of change in an operation pattern of a facility obtained from a distribution of occurrence times at which the predetermined event has occurred in the period of interest relative to an operation pattern of the facility obtained from a distribution of occurrence times at which the predetermined event has occurred in the reference period. The display control unit 14 performs display control on a display so that the degree of change calculated by the degree of change calculation unit 13 can be visualized.

An embodiment of the present disclosure has a feature in that, in order to detect a change in power consumption, the extent to an operation pattern of a facility in a period of interest has changed with reference to an operation pattern of the facility in a reference period is represented as an indicator of the “degree of change.” Therefore, the term “reference period” as used in the embodiment represents a period for which an operation pattern of a facility serving as a reference for calculating the degree of change is determined. On the other hand, the term “period of interest” represents a period for which there is obtained an operation pattern that is to be compared with the operation pattern in the reference period for calculating the degree of change. That is, the reference period is a period that serves as a reference for analyzing power consumption of a facility based on an operation pattern of the facility. The period of interest is a period for which power consumption of a facility is analyzed based on an operation pattern of the facility.

It should be clearly understood that both the reference period and the period of interest are some time in the past, as facility operation history information has been obtained. In an embodiment of the present disclosure, as the degree of change in power consumption in the period of interest relative to the reference period is obtained, the reference period is further in the past than the period of interest. For example, the period of interest may be the present week, month, or year, and the reference period may be the previous week, month, or year. The reference period and the period of interest may be non-successive periods. For example, the period of interest may be the present month, and the reference period may be the corresponding month in the previous year. For comparison purposes, while the period of interest may be of the same length as the reference period, they do not have to be periods of the same length. For example, the lengths of the respective periods may be determined according to a predetermined period-setting condition, such as a period for which a particular control is performed and a period for which it is not performed.

The elements 11 to 14 of the energy conservation assistance apparatus 10 are implemented by a cooperative operation of a computer that forms the energy conservation assistance apparatus 10 and a program that runs on the CPU 1 incorporated in the computer.

The program used in an embodiment of the present disclosure may be provided not only through a communication means, but also in the form of being stored in a computer-readable storage medium such as a CD-ROM or a USB memory. The program provided through a communication means or a storage medium is installed on the computer, and various steps of processing are implemented as the CPU of the computer sequentially executes the program.

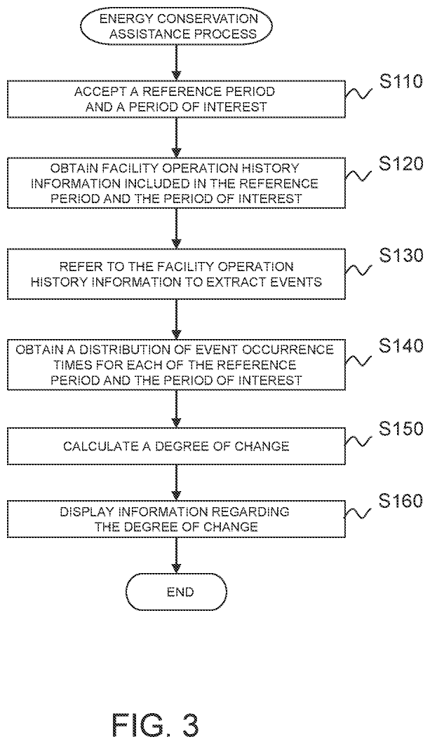

Next, an energy conservation assistance process according to an embodiment of the present disclosure will be described below using the flowchart given in FIG. 3.

First, a user inputs and designates a reference period and a period of interest for which they wish to confirm the degree of change in power consumption, via a predetermined period designation screen (not illustrated) shown on the display of the energy conservation assistance apparatus 10. The facility operation history information obtaining unit 11 accepts the reference period and the period of interest designated by the user (step S110) and then obtains, from the facility management apparatus 20, facility operation history information included in each of the reference period and the period of interest (step S120).

Subsequently, the event occurrence time extraction unit 12 refers to the obtained facility operation history information and extracts occurrence times at which a predetermined event has occurred in each of the reference period and the period of interest (step S130).

The predetermined event can be identified from data types and data values included in the facility operation history information. The predetermined event may be, for example, power-on or power-off of the facility. Specifically, the predetermined event may be a change of state that the power has switched from off to on, or inversely from on to off. For the facility that serves as an air conditioning facility, the predetermined event may be an event that a setting of the air conditioning facility has been changed to match a predetermined occurrence condition. The predetermined occurrence condition herein refers to, for example, a case where the set temperature of the air conditioning facility is raised or lowered, or a case where the set temperature of the air conditioning facility is raised or lowered by a predetermined temperature or greater, such as by 2° C. or more. The predetermined occurrence condition may refer to, for example, a case where the set temperature of the air conditioning facility is set to 25° C. Similarly, for the airflow rate of the air conditioning facility as well, the predetermined occurrence condition may refer to, for example, a case where the temperature is raised or lowered by a predetermined threshold value or greater, or set to high. The occurrence of a predetermined event given by way of example above can be detected by analyzing the facility operation history information.

It should be noted that the predetermined event does not have to be a single type of event but may include multiple events. However, for comparison purposes, the same events are to be extracted for the reference period and for the period of interest.

The predetermined event may be set beforehand. Alternatively, in addition to the reference period and the period of interest, the predetermined event may be designated by the user during the execution of the energy conservation assistance process. A facility for which the occurrence of the predetermined event is to be confirmed may be designated. In the description herein, the facility that undergoes the process is limited to a single device, for example, as it is set in the form of being incorporated in the predetermined event (for example, “facility A is on” is set as the predetermined event), or as it is designated by the user.

Subsequently, for each of the reference period and the period of interest, the degree of change calculation unit 13 obtains a distribution of occurrence times at which the extracted events have occurred (step S140).

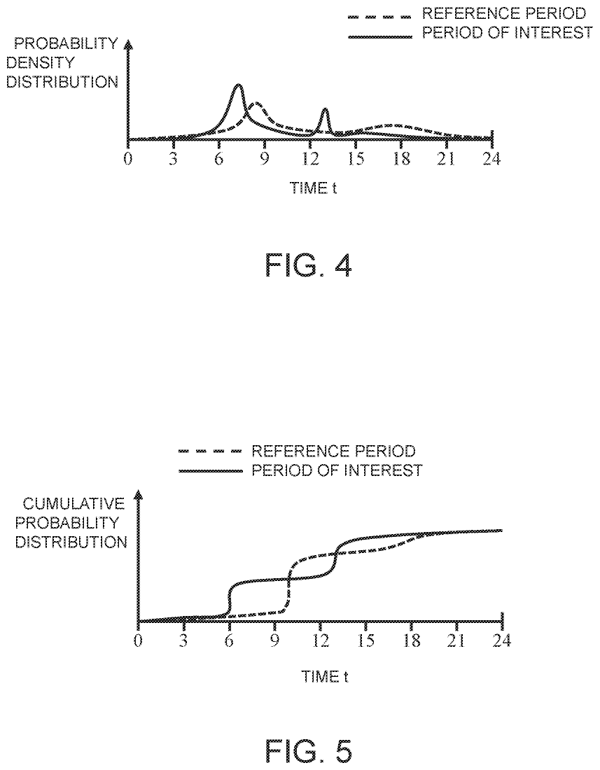

FIG. 4 illustrates an event occurrence count for each of the reference period and the period of interest in the form of a probability density distribution. In FIG. 4, the horizontal axis represents time, and the vertical axis represents probability density distribution. Time on the horizontal axis is given in hours from 0 to 24 for one day. For each period, event occurrences are counted for each hour, and the counted value serves as an event occurrence count for each hour. The ratio of an event occurrence count in each hour relative to an event occurrence count in the period serves as a probability density distribution. Therefore, a probability density distribution as integrated with respect to time t (=0 to 24) is 1.0.

The degree of change calculation unit 13 can obtain, from a distribution of occurrence times at which the predetermined event has occurred in the reference period, an operation pattern (denoted by a broken line in FIG. 4) in the facility that undergoes the process. Similarly, the degree of change calculation unit 13 can obtain, from a distribution of occurrence times at which the predetermined event has occurred in the period of interest, an operation pattern (denoted by a solid line in FIG. 4) in the facility that undergoes the process.

Subsequently, by comparing the operation patterns in the respective periods, the degree of change calculation unit 13 calculates a degree of change of the operation pattern corresponding to the period of interest relative to the operation pattern corresponding to the reference period (step S150). In an embodiment of the present disclosure, a KL (Kullback-Leibler) divergence of distributions is calculated as a degree of change. Assuming that a distribution of event occurrence times (operation pattern) in the reference period is p(t) and that a distribution of event occurrence times (operation pattern) in the period of interest is q(t), the degree of change (KL divergence KL(p∥q)) can be calculated by the following formula:

KL(p∥q)=Fₜp(t)log(p(t)/q(t))

The degree of change calculation unit 13 may also calculate a JS (Jensen-Shannon) divergence of distributions as a degree of change. In this case, the degree of change (JS divergence JS(p∥q)) can be calculated by the following formula:

JS(p∥q)=(KL(p∥q)+KL(q∥p))/2

The degree of change calculation unit 13 may also calculate a KS (Kolmogorov-Smirnov) test statistic of cumulative distributions as a degree of change. FIG. 5 illustrates an event occurrence count for each of the reference period and the period of interest in the form of a cumulative probability distribution. In FIG. 5, the horizontal axis represents time, and the vertical axis represents cumulative probability distribution.

The degree of change calculation unit 13 can obtain, from a cumulative distribution of occurrence times at which the predetermined event has occurred in the reference period, an operation pattern (denoted by a broken line in FIG. 5) in the facility that undergoes the process. Similarly, the degree of change calculation unit 13 can obtain, from a cumulative distribution of occurrence times at which the predetermined event has occurred in the period of interest, an operation pattern (denoted by a solid line in FIG. 5) in the facility that undergoes the process.

Assuming that a cumulative distribution of event occurrence times (operation pattern) in the reference period is P(t) and that a cumulative distribution of event occurrence times (operation pattern) in the period of interest is Q(t), the degree of change (KS test statistic KS(P, Q)) can be calculated by the following formula:

KS(P,Q)=supₜ|P(t)−Q(t)|

Other than the above, an Anderson-Darling test statistic may also be calculated as a degree of change.

As described above, multiple events can be set as the predetermined event. When multiple events are set, the degree of change calculation unit 13 calculates a degree of change for each event. By calculating, for example, an average value, a median value, a maximum value, or a minimum value of the degrees of change that are calculated for the respective events, a single degree of change is calculated for the facility. In this process, the events may be weighted. For example, a facility power on/off event is weighted relatively high, as it has a relatively large influence on power consumption. An event of raising a temperature setting of the air conditioning facility by PC is weighted relatively low, as it has a relatively small influence on power consumption.

A degree of change that has a relatively large value indicates that an operation pattern in the period of interest has changed by a relatively large amount with respect to an operation pattern of the facility in the reference period. An operation pattern may change in response to a change in event occurrence time or occurrence count. In response to a change in event occurrence time alone, as the occurrence count remains unchanged, the power consumption of the facility perhaps does not change by a large amount. However, a change in event occurrence count effects a change in power consumption of the facility. For example, it is believed that, when the facility is an air conditioning facility, an increase in count of events of lowering the set temperature in summer increases power consumption. Conversely, it is believed that an increase in count of events of lowering the set temperature in winter reduces power consumption. In such cases, power consumption changes by a relatively large amount.

In consideration of the above, the display control unit 14 determines and notifies the user that power consumption has changed by a large amount when the degree of change is greater than or equal to a predetermined threshold value. This enables the user to begin considering whether or not the energy conservation control plan should be revised. In an embodiment of the present disclosure, after the degree of change calculation unit 13 calculates a degree of change, the display control unit 14 causes a display to display information regarding the degree of change (step S160) regardless of whether the degree of change is large or small.

It should be noted that information may be output to elsewhere other than the display. For example, information may be saved in a file and output to, for example, the HDD 4 or other storage means, and thereby stored therein. Alternatively, information may be transmitted to a different apparatus via a network. In an embodiment of the present disclosure, as information is displayed on the display, the display control unit 14 is provided, but an output control means that suits where information is output may be provided.

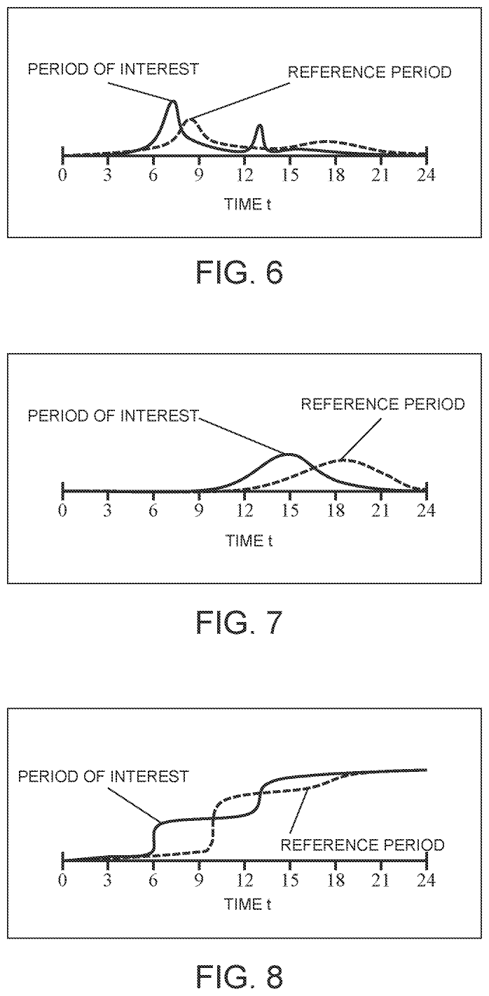

FIGS. 6 to 8 illustrate examples of display of information regarding a degree of change (hereinafter simply referred to as “information”) for presentation to a user. FIG. 6 illustrates a probability density distribution of power-on event occurrence times of a facility (for example, facility A) for each of the reference period and the period of interest. FIG. 7 illustrates a probability density distribution of power-off event occurrence times of the facility A for each of the reference period and the period of interest. FIG. 8 illustrates a cumulative distribution of power-on event occurrence times of the facility A for each of the reference period and the period of interest. In these figures, the horizontal axis represents time, which is, as described above in relation to FIG. 4, given in hours from 0 to 24 for one day. The vertical axis in FIGS. 6 and 7 represents probability density distribution, and the vertical axis in FIG. 8 represents cumulative distribution thereof.

FIG. 6 corresponds to FIG. 4 that shows a probability distribution when the KL divergence described above is calculated as a degree of change. As a degree of change value is presented, the user can know the degree of change in power consumption but does not specifically know what change has occurred. In consideration of the above, in an embodiment of the present disclosure, as illustrated in FIGS. 6 to 8 by way of example, specific changes in operation patterns are displayed in visually recognizable form.

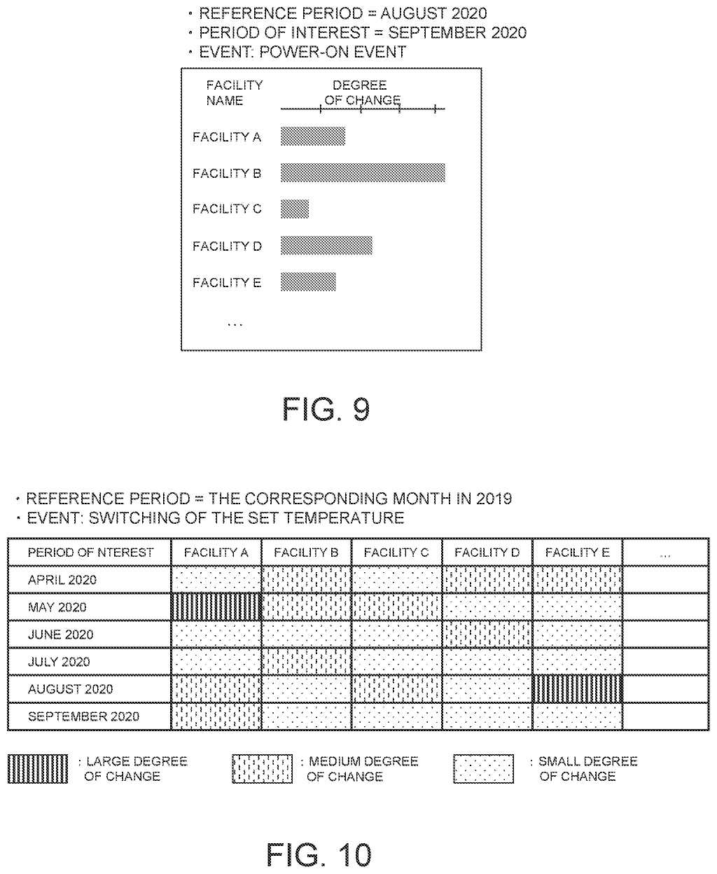

FIG. 9 illustrates an example of display in which a degree of change for each facility is given in bar graph form. The user who refers to the graph illustrated in FIG. 9 can know that the operation pattern of a facility B has changed by a large amount in comparison with the previous month.

FIG. 10 illustrates an example of display in which a degree of change from the previous month is given for each facility in heat map form. The user who refers to the graph illustrated in FIG. 10 can know the degree of change in operation pattern for each facility relative to the corresponding month in the previous year.

As described above, according to an embodiment of the present disclosure, information that can assist in creating an energy conservation control plan can be presented to a user. As a result, the user who refers to the presented display information can take measures, such as revising an energy conservation control plan especially for a facility with a large degree of change.

### REFERENCE SIGNS LIST

1 CPU
2 ROM
3 RAM
4 hard disk drive (HDD)
5 network interface (IF)
6 user interface (UI)
7 internal bus
10 energy conservation assistance apparatus
11 facility operation history information obtaining unit
12 event occurrence time extraction unit
13 degree of change calculation unit
14 display control unit
20 facility management apparatus
21 facility operation history information storage unit

1. A power consumption monitoring apparatus comprising a processor, the processor being configured to:
refer to facility operation history information to extract occurrence times at which a predetermined event has occurred in each of a reference period and a period of interest, the reference period serving as a reference for analyzing power consumption of a facility, and the period of interest serving as a subject of analysis;
calculate a degree of change in an operation pattern of the facility obtained from a distribution of the occurrence times at which the predetermined event has occurred in the period of interest, relative to an operation pattern of the facility obtained from a distribution of the occurrence times at which the predetermined event has occurred in the reference period; and
output the calculated degree of change.

2. The power consumption monitoring apparatus according to claim 1, wherein the predetermined event is a power-on or power-off event of the facility.

3. The power consumption monitoring apparatus according to claim 1, wherein when the facility is an air conditioning facility, the predetermined event is an event that a setting of the air conditioning facility has been changed to match a predetermined occurrence condition.

4. The power consumption monitoring apparatus according to claim 1, wherein the processor calculates a KL divergence or a JS divergence as a degree of change.

5. The power consumption monitoring apparatus according to claim 1, wherein the processor calculates a KS test statistic or an Anderson-Darling test statistic as a degree of change.

6. The power consumption monitoring apparatus according to claim 1, wherein when multiple events are set as the predetermined event, the processor calculates a degree of change for each event and weights the degrees of change that are calculated for the respective events, to calculate a single degree of change.
